(19) United States
(12) Patent Application Publication
(10) Pub. No.: US 2013/0265699 A1
(43) Pub. Date: Oct. 10, 2013

(54) SEALED HINGE FOR CASING AND ELECTRONIC DEVICE USING THE SAME

(71) Applicant: XIAO-HUI ZHOU, Shenzhen City (CN)

(72) Inventor: XIAO-HUI ZHOU, Shenzhen City (CN)

(21) Appl. No.: 13/649,151

(22) Filed: Oct. 11, 2012

(30) Foreign Application Priority Data
Apr. 6, 2012 (CN) 201210098865.7

(51) Int. Cl. H05K 5/03; H05K 5/06

(52) U.S. Cl. 361/679.01; 312/296

(57) ABSTRACT

An electronic device includes a bottom casing, an upper casing, a hinge, and a dust proof casing. The upper casing is assembled to the bottom casing to form a space. The upper casing defines a first opening in one side. The bottom casing further includes a first fixing member located in the first opening. A part of the hinge is received in the space, and the other part of the hinge protrudes out of the upper casing via the first opening. The dust proof casing includes a cover, and a second fixing member protruding from the cover to cooperate with the first fixing member so as to enable the cover to be assembled to the upper casing, and enable the cover to cooperate with the hinge to seal the first opening.

### BACKGROUND

1. Technical Field

The present disclosure relates to electronic devices, particular to a casing of an electronic device, and an electronic device.

2. Description of Related Art

A folded electronic device, such as a DVD player or a notebook computer, includes a casing for receiving circuit boards, power supplies, and other electronic components, a lid with a display, and a hinge member connected to the lid and the casing to enable the lid to rotate up. Typically, a part of the hinge member is received in the housing, and the casing defines an opening to enable the other part of the hinge member to protrude out of the housing. However, dust can easily enter into the casing via the opening and affect the performance and life of the electronic device.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of an electronic device.

FIG. 2 is an explored view of the electronic device in FIG. 1.

FIG. 3 is an inverted view of the electronic device in FIG. 2.

FIG. 4 is an enlarged view of circle IV in FIG. 3.

FIG. 5 is an isometric view of a dust proof casing of the electronic device in FIG. 1.

FIG. 6 is a partial enlarged view of the dust proof casing in FIG. 5 when the dust proof casing is assembled to a casing of the electronic device.

### DETAILED DESCRIPTION

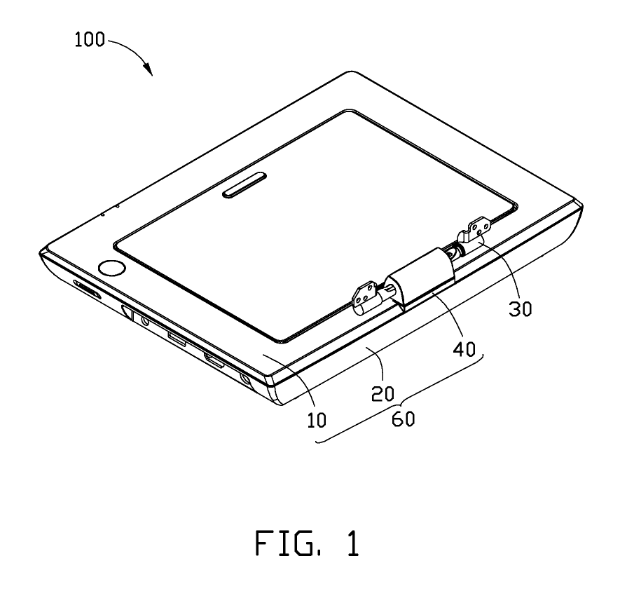

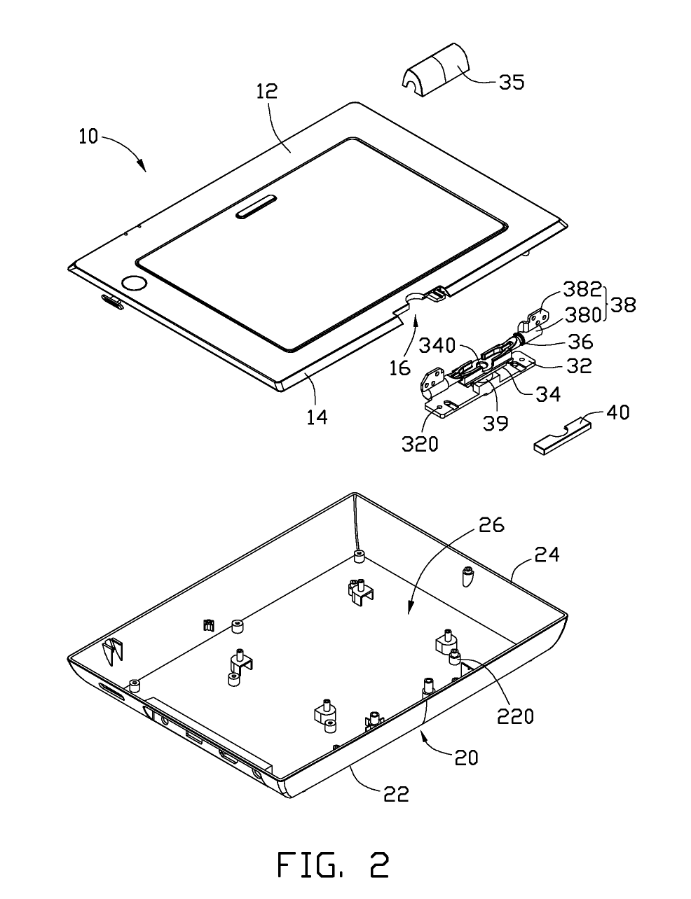

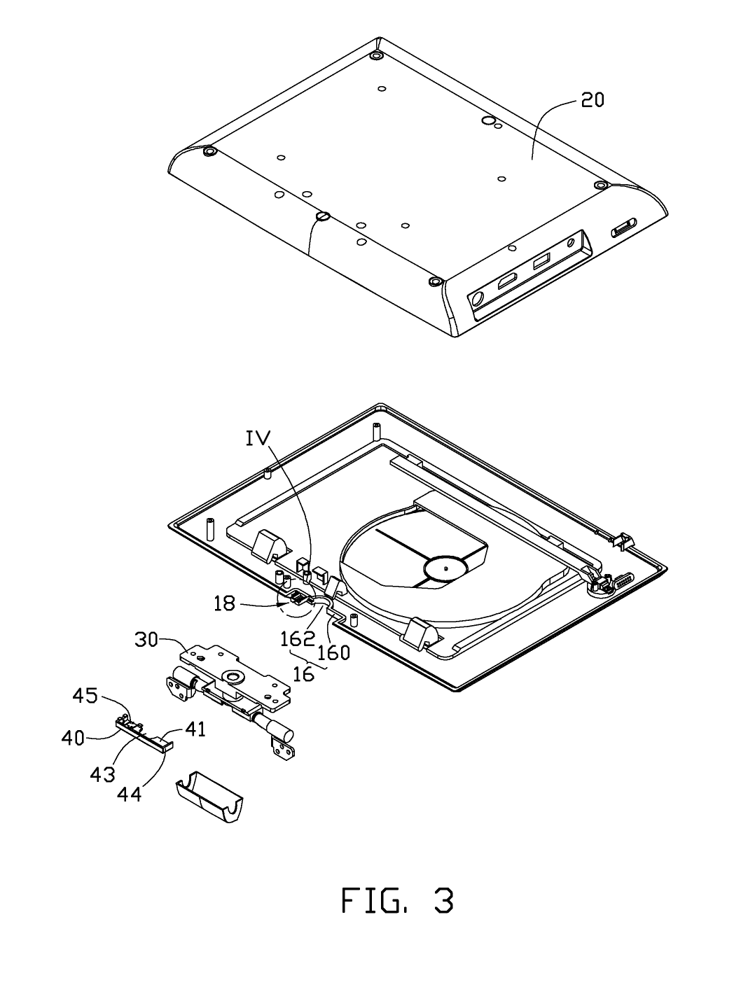

Referring to FIGS. 1-3, an electronic device 100 includes an upper casing 10, a bottom casing 20, a hinge 30, and a dust proof casing 40. The upper casing 10 is assembled to the bottom casing 20 to form a space between the bottom casing 20 and the upper casing 10. A plurality of electronic elements (not shown) are received in the space. The electronic elements may be circuit boards, power supplies, wires and the like. A part of the hinge 30 is secured to the bottom casing 20, and the other part of the hinge 30 protrudes out of the upper casing 10. The dust proof casing 40 is assembled to the upper casing 10 to cooperate with the hinge 30 to seal the upper casing 10. In other words, the upper casing 10, the bottom casing 20, and the dust proof casing 40 form a casing 60 to prevent dust from entering into a gap between the hinge 30 and the upper casing 10.

The bottom casing 20 includes a rectangular bottom board 22, and four first sidewalls 24 protruding from four edges of the bottom board 22 and cooperating with the bottom board 22 to form a receiving space 26. The bottom board 22 carries a plurality of fixing posts 220, the fixing posts 220 are adjacent to one of the first sidewalls 24.

The hinge 30 includes a base 32, a securing member 34, a shield 35, two rotating shafts 36, two rotating members 38, and a connecting member 39. The base 32 is secured to the bottom casing 20. The securing member 34 is connected to the base 32 via the connecting member 39, and the securing member 34 is away from the bottom casing 20. The two rotating shafts 36 extend out of opposite ends of the securing member 34. The two rotating member 38 are sleeved on the rotating shafts 36 and capable of rotating with respect to the rotating shafts 36.

The base 32 is a rectangular board. The base 32 defines a plurality of fixing holes 320. The fixing holes 320 correspond to the fixing posts 220. The base 32 is received in the receiving space 26, and a plurality of screws (not shown) pass through the fixing holes 320 to screw into the fixing posts 220. The hinge 30 is thereby secured to one side of the bottom case 20.

The securing member 34 defines a through hole 340 at the middle. The shield 35 covers the securing member 34 to hide the through hole 340.

The connecting part 39 which connects the base 32 and the securing member 34 is columnar.

The rotating shafts 36 are columnar, and extend from the opposite ends of the securing member 34 in opposite directions.

Each rotating member 38 includes a sleeve 380, and a mounting portion 382 connected to the sleeve 380. The sleeve 380 sleeves on the rotating shaft 36, and the sleeve 380 is capable of rotating with respect to the rotating shaft 36. The mounting portion 382 is capable of being mounted to the lid (not shown), and enables the lid to rotate with respect to the rotating shafts 36. The lid can thus be closed and opened with respect to the upper casing 10.

The upper casing 10 includes a rectangular top board 12, four second sidewalls 14 extending downwards from four edges of the top board 12, and a first opening 16. The four second sidewalls 14 are connected end-to-end. The first opening 16 is defined in one side of the top board 12.

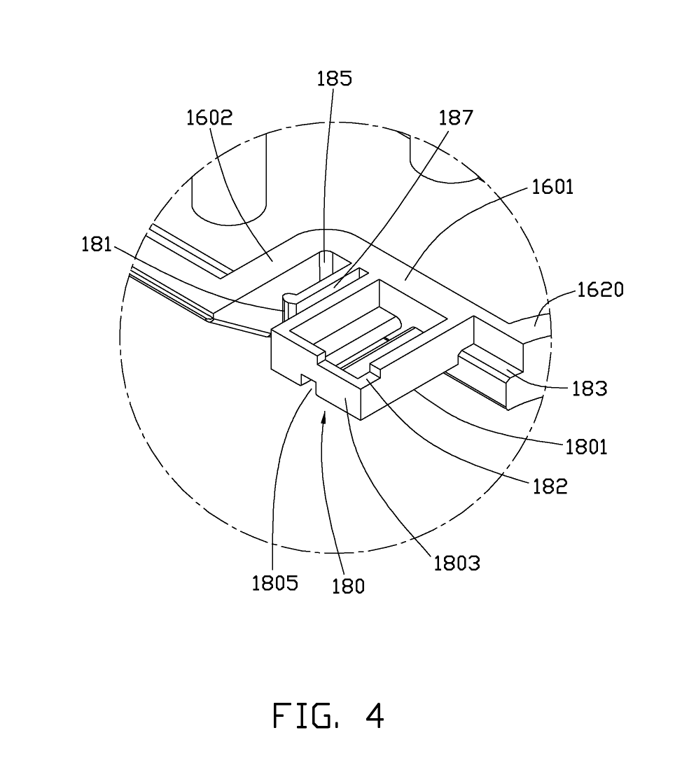

Referring to FIG. 4, the first opening 16 includes a front opening 160, and a rear opening 162 communicating with the front opening 160. The front opening 160 is rectangular, and passes through the top board 12 and through one of the second sidewalls 14. The rear opening 162 is semi-circular. The rear opening 162 passes through the top board 12. The center line of the rear opening 162 is a center line of the front opening 160.

The upper casing 10 further includes a first flange 1620 around the rear opening 162. The first flange 1620 is semi-circular, and matches the connecting part 39. The upper casing 10 further includes two second flanges 1601, and two third flanges 1602. The front opening 160 is surrounded by the two second flanges 1601 and two third flanges 1602 except for a break or gap. The two second flanges 160 are joined to the two ends of the first flange 162, and extend in opposite directions parallel to the second sidewalls 14 in which the front opening 160 is located. The third flanges 1602 are connected to the ends of the two second flanges 1601, and perpendicular to the second flanges 1601. A first fixing member 18 protrudes from one of the second flanges 1601 towards one side of the front opening 160 which is away from the rear opening 162.

The first fixing member 18 includes a guiding element 180, a hook 181, a first recess 182, a second recess 183, a first gap 185, and a second gap 187. The guiding element 180 and the hook 181 extend from the second flange 1601 towards one side of the front opening 160 which is away from the rear opening 162. The guiding element 180 extends from the middle of the second flange 1601. The hook 181 is positioned at one side of the guiding element 180 and away from the rear opening 162. The first recess 182 is defined in the guiding element 180. The second recess 183 is defined in the second flange 1601. The first gap 185 is defined between the hook 181 and one of the third flanges 1602. The second gap 187 is defined between the hook 181 and the guiding element 180.

The guiding member 180 includes a bottom board 1801 parallel to the top board 12, and three side boards 1803 extending down from three edges of the bottom board 1801. Two side boards 1803 are perpendicularly connected to the second flange 1601. The third side board 1803 faces the second flange 1601, and is connected between the other two side boards 1803. The bottom board 1801 defines a guiding groove 1805. The groove 1805 runs from the second flange 1601 towards the side board 1803 facing the second flange 1601.

The first recess 182 is a concavity recessed into a joint of the two side boards 1803. The first recess 182 is away from the bottom board 1801 and adjacent to the rear opening 162.

The second recess 183 is defined in the second flange 1601 and adjacent to the rear opening 162. The second recess 183 is also a concavity recessed into the second flange 1601.

The hook 181 is shorter than the guiding element 180. One end of the hook 181 is curved towards the third flange 1602.

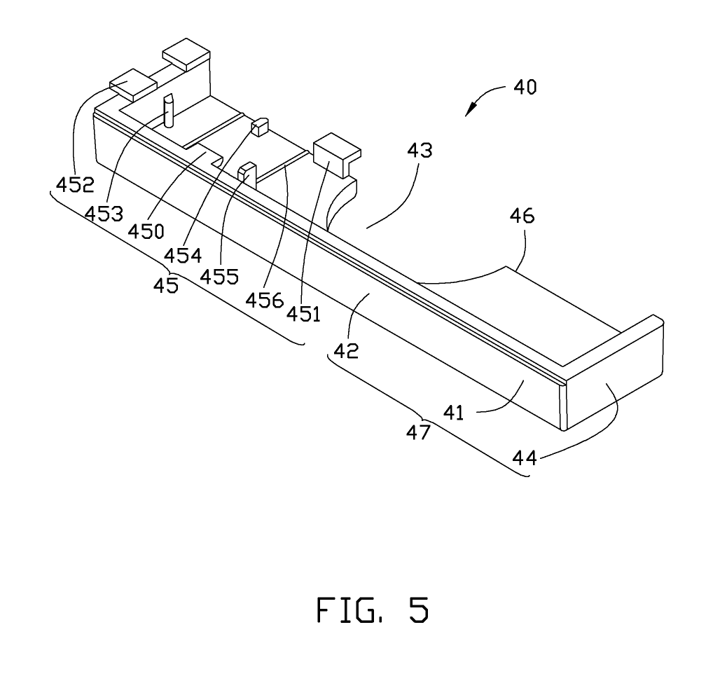

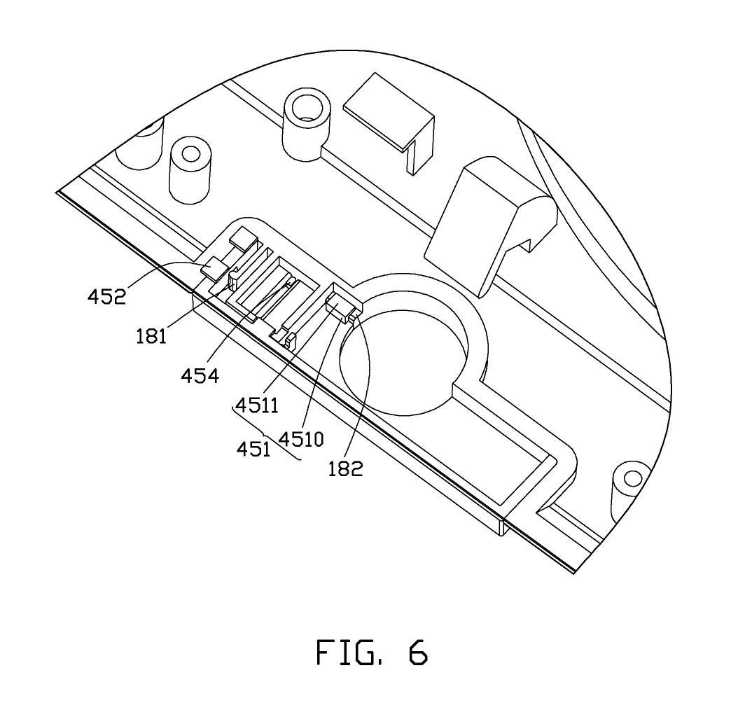

Referring to FIGS. 5-6, the dust proof casing 40 includes a cover 47, a second opening 43, and a second fixing member 45.

The cover 47 envelops the front opening 160. The cover 47 includes an upper portion 41, a third sidewall 42, and two parallel fourth sidewalls 44. The third sidewall 42 and the two fourth sidewalls 44 perpendicularly protrude from three ends of the upper portion 41. The upper portion 41, the third side wall 42, and the fourth sidewalls 44 are rectangular boards. The third sidewall 42 is connected between the two fourth sidewalls 44.

The second opening 43 is semi-circular. The second opening 43 runs from the middle of a free end 46 of the top board 12. A diameter of the second opening 43 is the same as the diameter of rear opening 162. When the dust proof casing 40 is assembled to the upper casing 10, the second opening 43 and the rear opening 162 form a circular opening to receive the connecting part 39, and enable the dust proof casing 40 to mate with the connecting part 39.

The second fixing member 45 includes a first supporting member 450, a second supporting member 451, two third supporting members 452, and a hooking rib 453, a sliding block 454, a stopping member 455, and two sliding ribs 456. The first supporting member 450 is positioned at the third sidewall 42. The second supporting member 451, the sliding ribs 456, the sliding block 454, and the stopping member 455 are positioned at the upper portion 41. The third supporting members 452 and the hooking rib 453 are positioned on one of the fourth sidewalls 44.

The first supporting member 450 corresponds to the first recess 182, the first supporting member 450 is a flat board perpendicularly protruding from an inner surface of the third sidewall 42, and is adjacent to the end of the third sidewall 42.

The sliding ribs 456 are parallel to each other, and arranged on the inner surface of the upper portion and on one side of the second opening 43. The sliding ribs 456 perpendicularly extend from the third sidewall 42 towards the free end 46 of the upper portion 41. The sliding member 454 is columnar, and is positioned in the middle of the sliding ribs 456, and adjacent to the free end 46. The stopping member 455 is a broad strip, and positioned on one side of the sliding rib 456 adjacent to the second opening 43.

The second supporting member 451 corresponds to the second recess 183, and the second supporting member 451 is positioned on one side of the stopping member 455 adjacent to the second recess 183. The second supporting member 451 includes a protrusion 4510 extending from the inner surface of the upper portion 41, and a supporting board 4512 perpendicularly extending from the end of the protrusion 4510. The supporting board 4512 extends out of the upper portion 41.

The second supporting members 452 are positioned at intervals at the end of the fourth sidewall 44 away from the upper portion 41. The second supporting members 452 are broad plates extending out of the upper portion 41. The hooking rib 453 protrudes from the inner surface of the fourth sidewall 44 and corresponds to the hook 181.

Referring to FIG. 6, assembly of the electronic device 100 is described below. First, the hinge 30 is secured to the bottom casing 20, the connecting part 39, the securing member 34, the rotating shafts 36, and the rotating members 38 are located on the bottom housing 20. Second, the upper casing 10 is brought to clasp the bottom casing 20, and the connecting part 39 is received in the rear opening 162 which tightly mates with the connecting part 39. Third, the dust proof casing 40 is assembled to the upper casing 10 to cover the first opening 16 to enable the upper casing 10 to be sealed. The assembly of the dust proof casing 40 to the upper casing 10 is described below.

First, the dust proof casing 40 is placed on the guiding element 180, the inner surface of the upper cover 41 which protrudes from the second fixing member 45 faces the bottom casing 20, the end 46 of the upper cover 41 faces the first opening 16, and the fourth sidewalls 44 are joined to the third flanges 1602. At this time, the sliding member 454 is inserted into the guiding groove 1805, the sliding ribs 456 are positioned on the surface of the bottom board 1801 opposite to the bottom casing 20, and the second fixing member 45 faces the first fixing member 18. Second, the dust proof casing 40 is moved to the upper casing 10 along the guiding groove 1805 to enable the end of the upper cover 46 to be joined to the second flange 1601. At this time, the second opening 43 and the rear opening 162 cooperatively form a circular opening to receive the connecting part 39, and the first flange 1620 and the upper cover 41 are tightly mated with the connecting part 39. The first supporting member 450 is inserted into the first recess 181 to support the guiding element 180, the second supporting member 451 is inserted into the second recess 183 to support the second flange member 1601, and the third supporting members 452 support the ends of the third flange member 1602. The hook 181 holds the hooking rib 453.

Because the first supporting member 450, the second supporting member 451, and the third supporting member 452 support the upper casing 10, the guiding element 180 supports the dust proof casing 40, and the dust proof casing 40 is prevented from moving vertically. Further, the hook 181 holds the hooking rib 453 away from the end 46, the end 46 is stopped by the second flanges 1601, therefore the dust proof casing 40 is prevented from moving horizontally.

As described above, the dust proof casing 40 is capable of covering the first opening 16 to seal the upper casing 10, so dust can be prevented from coming into the interior of the electronic device 100. Therefore, the electronic device 100 will be kept clean so as to extend the life of the electronic components located inside the electronic device 100.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a bottom casing;
an upper casing assembled to the bottom casing to form a space, the upper casing defining a first opening in one side, and the upper casing comprising a first fixing member located in the first opening;
a hinge with a part being received in the space, and the other part being protruding out of the upper casing via the first opening; and
a dust proof casing comprising a cover, and a second fixing member protruding from the cover to cooperate with the first fixing member as to enable the cover to be assembled to the upper casing, and enable the cover to cooperate with the hinge to seal the first opening.

2. The electronic device of claim 1, wherein the first fixing member comprises a hook protruding from the upper cover and located in the first opening, the fixing member comprises a hooking rib protruding from the cover, the hook clasps the hooking rib to prevent the dust proof casing from moving with respect to the upper casing in a horizontal direction.

3. The electronic device of claim 2, wherein the upper cover comprising a flange, the first opening is surrounded by the flange except a gap which allows the dust proof casing to move to the first opening, the hook protrudes from one side of the flange facing the gap.

4. The electronic device of claim 1, wherein the first fixing member comprises a guiding element, the dust proof casing is supported by the guiding member, the dust proof casing further comprises first supporting members for supporting the upper cover, as a result, the dust proof casing is prevented from moving in a direction perpendicular to the horizontal direction.

5. The electronic device of claim 4, wherein the first supporting members supports one end of the flange away from the upper casing.

6. The electronic device of claim 4, wherein the dust proof casing further comprises a second supporting member, the second supporting member supports one end the guiding member away from the cover.

7. The electronic device of claim 6, wherein the guiding member defines a recess to received the supporting member.

8. The electronic device of claim 1, wherein the cover defines a second opening which cooperates with the first opening to form a circular opening.

9. The electronic device of claim 8, wherein the first opening comprising a front opening and a rear opening communicating with the front opening, the rear opening and the second opening form the circular opening to receive a part of the hinge, the cover covers the front opening.

10. A casing, comprising:
a bottom casing;
an upper casing assembled to the bottom casing to form a space, the upper casing defining a first opening in one side for allowing a hinge received in the space to project out of the upper casing, and the upper casing comprising a first fixing member located in the first opening; and
a dust proof casing comprising a cover, and a second fixing member protruding from the cover to cooperate with the first fixing member as to enable the cover to be assembled to the upper casing, and enable the cover to cooperate with the hinge to seal the first opening.

11. The casing of claim 10, wherein the first fixing member comprises a hook protruding from the upper cover and located in the first opening, the fixing member comprises a hooking rib protruding from the cover, the hook clasps the hooking rib to prevent the dust proof casing from moving with respect to the upper casing in a horizontal direction.

12. The casing of claim 11, wherein the upper cover comprising a flange, the first opening is surrounded by the flange except a gap which allows the dust proof casing moving to the first opening, the hook protrudes from one side of the flange facing the gap.

13. The casing of claim 11, wherein the first fixing member comprises a guiding element, the dust proof casing is supported by the guiding member, the dust proof casing further comprises first supporting members for supporting the upper cover, as a result, the dust proof casing is prevented from moving in a direction perpendicular to the horizontal direction.

14. The casing of claim 13, wherein the first supporting members supports one end of the flange away from the upper casing.

15. The casing of claim 13, wherein the dust proof casing further comprises a second supporting member, the second supporting member supports one end the guiding member away from the cover.

16. The casing of claim 15, wherein the guiding member defines a recess to received the supporting member.

17. The casing of claim 16, wherein the cover defines a second opening which cooperates with the first opening to form a circular opening.

18. The casing of claim 17, wherein the first opening comprising a front opening and a rear opening communicating with the front opening, the rear opening and the second opening form the circular opening to receive a part of the hinge, the cover covers the front opening.
